(19) United States
(12) Patent Application Publication
(10) Pub. No.: US 2026/0303070 A1
(43) Pub. Date: Oct. 1, 2026

(54) DUTY-CYCLE ERROR CORRECTION AND REFERENCE SPUR REDUCTION TECHNIQUES FOR PLLS WITH REFERENCE FREQUENCY-DOUBLERS

(71) Applicant: Silicon Laboratories Inc., Austin, TX (US)

(72) Inventors: Abdulkerim L. Coban, Austin, TX (US); Wenhuan Yu, Austin, TX (US); Mustafa H. Koroglu, Austin, TX (US)

(21) Appl. No.: 19/089,315

(22) Filed: Mar. 25, 2025

(51) Int. Cl. H03K 3/017; H03K 17/687; H03L 7/08

(52) U.S. Cl. CPC H03K 3/017; H03K 17/687; H03L 7/08

(57) ABSTRACT

A squaring buffer circuit generates a square wave signal from a low edge rate input signal. The squaring buffer circuit has a first inverter that receives the input signal and supplies a square wave output signal. A bias circuit provides a bias voltage to the first inverter input. The bias circuit includes a second inverter, which is a scaled replica of the first inverter. The second inverter has the input shorted to the output. A resistor is coupled between the second inverter output and the first inverter input. A frequency doubler circuit receives the square wave signal supplies a frequency doubled signal to a phase-locked loop (PLL). A duty cycle error correction circuit is responsive to a duty cycle error to adjust PMOS or NMOS strength of the first inverter to reduce the duty cycle error.

### BACKGROUND

### Field of the Invention

This disclosure relates to duty-cycle error correction and spur reduction in phase-locked loops.

### Description of the Related Art

Phase-locked loops (PLLs) preferably use higher frequency reference clocks in order to reduce overall phase-noise, particularly for PLLs used for synthesizers in radio frequency (RF) applications. A high frequency reference clock signal facilitates use of a wider PLL loop bandwidth, which is limited by stability requirements set by the reference clock frequency. A wider bandwidth PLL allows better voltage controlled oscillator (VCO) noise suppression and also results in faster loop settling. On the other hand, keeping bandwidth low with an increased reference clock frequency, typically reduces the reference path noise (e.g., from the crystal oscillator (XO) supplying the reference clock and its associated circuitry).

A higher frequency reference clock signal is typically achieved simply by doubling the frequency for the input clock signal that is sourced, e.g., from a clock source such as a crystal oscillator. A frequency doubler circuit is often implemented by XORing the input clock signal with a delayed version of the input clock signal. The PLL then uses the rising edge of the output clock signal with the doubled frequency from the frequency doubler circuit as the reference clock signal.

Since the frequency doubler circuit uses both edges of the input clock signal from the clock source, any duty-cycle error present in the input clock signal results in an effective jitter on the frequency doubled output clock. That jitter causes reference spurs on the final PLL output clock. In addition, depending on the actual PLL implementation, the duty-cycle error can cause PLL noise folding due to loop non-linearity. Some phase-detectors, particularly those used in digital PLLs, can have limited range, which places an upper limit on how much duty-cycle error can be tolerated.

Reference spurs can be reduced by calibrating the duty-cycle of the incoming clock to 50%. The correction point is typically the squaring buffer at the clock source output. FIGS. 1 and 2 illustrate prior art approaches to implementing squaring buffers. FIG. 1 shows a prior art squaring buffer circuit 100. Inverter 102 implements the squaring buffer. The inverter 102 receives an input sinusoidal signal 103 and changes state at the slicing point, e.g., from a logical 0 to a logical 1 or from 1 to 0. Capacitor 104 provides AC-coupling of the input sinusoidal signal that is being converted to a square wave by the squaring buffer. Additional buffer stages 106 may follow the inverter 102. The bias resistor Rb connects to the Vbias terminal 108 and provides a bias voltage on the input of inverter 102. The approach illustrated in FIG. 1 is suitable for analog control of the slicing point using an analog duty cycle distortion (DCD) correction loop. DCD is also referred to herein as duty cycle error. Correction from the Vbias terminal by adjusting the slicing point is the main duty-cycle adjustment scheme but this technique is often slow due to the large RbCb time constant. The duty cycle of the square wave provided by the squaring buffer circuit 100 is highly sensitive to process, voltage, and temperature (PVT) variations.

FIG. 2 illustrates the effect of the slicing point on the duty cycle of the output square wave. The squaring buffer receives the sinusoidal input clock signal 202. A slicing point at 204 results in a square wave 206 with a greater than 50% duty cycle while a slicing point at 208 results in a square wave 210 with a 50% duty cycle.

FIG. 3 illustrates another prior art squaring buffer, a self-biased squaring buffer. The approach is self-biasing using feedback resistor 304 for the inverter 302. Digital tuning is possible, however, such tuning can require a large PMOS/NMOS ratio change to achieve the desired results. In the embodiment of FIG. 3, the DCD is less sensitive to PVT variations as compared to “fixed input bias” solution shown in FIG. 1.

While the approaches in FIGS. 1 and 3 provide the squaring function for an input sinusoid, further improvements to reduce spurs caused by duty cycle errors is desirable. Accordingly, improved approaches to calibrating the duty cycle of the PLL input clock signal and reducing reference spurs in the PLL output clock are desirable.

### SUMMARY OF EMBODIMENTS

In an embodiment an apparatus includes a squaring buffer circuit. The squaring buffer circuit has a first inverter having a first inverter input coupled to an input signal and a first inverter output supplying a square wave signal. A bias circuit provides a bias voltage to the first inverter input. The bias circuit includes a second inverter, which is a scaled replica of the first inverter, and the bias circuit has a second inverter input shorted to a second inverter output and a resistor coupled between the second inverter output and the first inverter input.

In another embodiment a method for generating a square wave signal from a low edge rate input signal includes supplying the input signal to a first inverter of a squaring buffer circuit and supplying the square wave signal from the first inverter. The method further includes generating a bias voltage for the first inverter using a second inverter having a second inverter input shorted to a second inverter output and a resistor coupled between the second inverter output and a first inverter input.

In another embodiment an apparatus includes a squaring buffer circuit. The squaring buffer circuit includes a first inverter having a first inverter input coupled to a low edge rate input signal and a first inverter output supplying a square wave signal. The first inverter includes a programmable portion. A bias circuit provides a bias voltage to the first inverter input. The bias circuit includes a second inverter having a second inverter input shorted to a second inverter output, the second inverter being a scaled version of a fixed portion of the first inverter. The bias circuit further includes a resistor coupled between the second inverter output and the first inverter input. A frequency doubler circuit is coupled to the square wave signal and is configured to supply a frequency doubled signal. A phase-locked loop is coupled to the frequency doubled signal. The phase-locked loop includes a phase detector coupled to the frequency doubled signal and to a feedback divider signal. A loop filter is coupled to the phase detector and an oscillator is coupled to the loop filter and configured to supply an oscillator output signal. A feedback divider is coupled to the oscillator output signal and is configured to supply the feedback divider signal. A duty cycle error correction circuit is responsive to a duty cycle error to adjust one or more duty cycle adjust signals to adjust PMOS or NMOS strength of the first inverter to reduce the duty cycle error. The duty cycle error correction circuit is configured to adjust the one or more duty cycle adjust signals based, at least in part, on a value of the square wave signal.

### BRIEF DESCRIPTION OF THE DRAWINGS

The present invention may be better understood, and its numerous objects, features, and advantages made apparent to those skilled in the art by referencing the accompanying drawings.

FIG. 1 illustrates a prior art squaring buffer.

FIG. 2 illustrates how the slicing point affects the duty cycle.

FIG. 3 illustrates another prior art squaring buffer.

FIG. 4 illustrates three main components of an embodiment of a system that reduces duty cycle error and jitter.

FIG. 5 illustrates the spurs resulting from a duty cycle error in the clock signal generated by the squaring buffer.

FIG. 6 illustrates the spur reduction that occurs when a duty cycle correction loop calibrates the squaring buffer.

FIG. 7 illustrates additional details of an embodiment of the squaring buffer circuit.

FIG. 8 illustrates a calibration operation for the squaring buffer.

FIG. 9A is a timing diagram showing the relationship between the frequency doubled clock and the PLL feedback clock for an input 1x refence clock signal having a duty cycle less than 50%.

FIG. 9B is a timing diagram showing the relationship between the frequency doubled clock and the PLL feedback clock for an input 1x reference clock signal having a duty cycle more than 50%

FIG. 10A illustrates the relationship of sampling clocks to the frequency doubled clock signal when the duty cycle of the input 1x reference clock signal is 50%.

FIG. 10B illustrates the relationship of sampling clocks to the frequency doubled clock signal when the duty cycle of the input 1x reference clock signal is less than 50%.

FIG. 10C illustrates the relationship of sampling clocks to the frequency doubled clock signal when the duty cycle of the input 1x reference clock signal is more than 50%.

FIG. 11 illustrates an embodiment DC error correction logic that provides the control structure for the DC correction loop.

FIG. 12 is a table showing the duty-cycle adjustment counter control based on the sampled value of CLK_1xFREF and the sampled values of CLK_2xFREF by the sample clocks.

FIG. 13A illustrates the change in the DC adjustment code during a duty cycle adjustment operation.

FIG. 13B illustrates the change in duty cycle during a duty cycle adjustment operation.

FIG. 13C illustrates the PLL VCO control voltage during the duty cycle adjustment operation.

FIG. 13D illustrates a more detailed view of the PLL VCO control voltage during the duty cycle adjustment operation.

FIG. 14 illustrates an embodiment of the notch filter implementation in a z-domain representation and in a block diagram form.

FIG. 15 illustrates how the notch filter in the PLL at the frequency (fref) of the clock supplied to the frequency doubler circuit further reduces spurs on the PLL output.

FIG. 16 illustrates the magnitude response of the notch filter.

FIG. 17 illustrates an embodiment in which the phase detector in the PLL is implemented as a time to digital converter (TDC) that provides information to the DC error correction logic that indicates the duty cycle error.

FIG. 18 is a timing diagram illustrating the operation of the embodiment shown in FIG. 17.

FIG. 19 is a high level block diagram of an embodiment of the duty cycle error correction logic that receives information from the TDC.

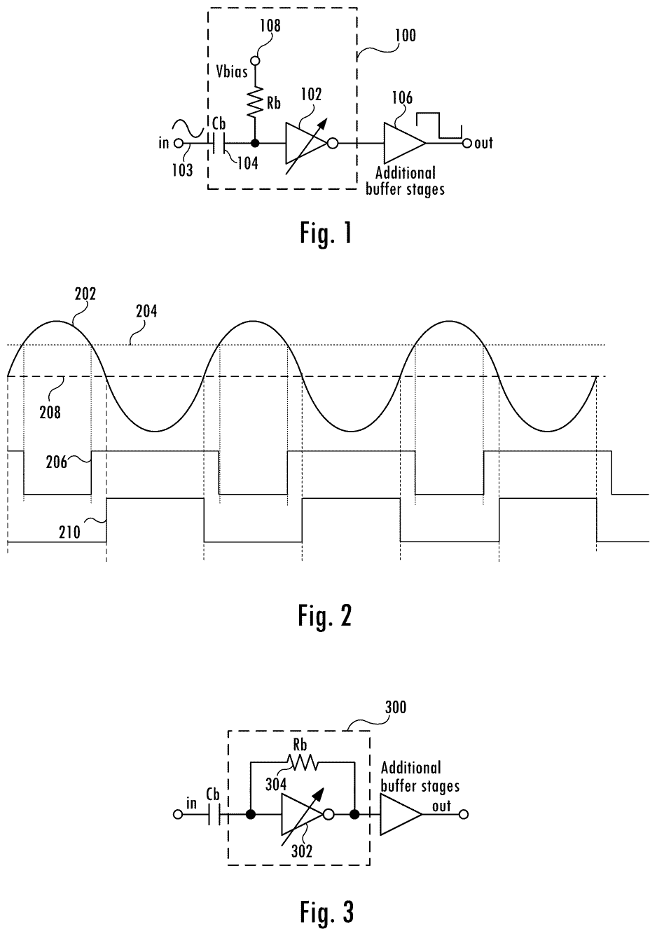

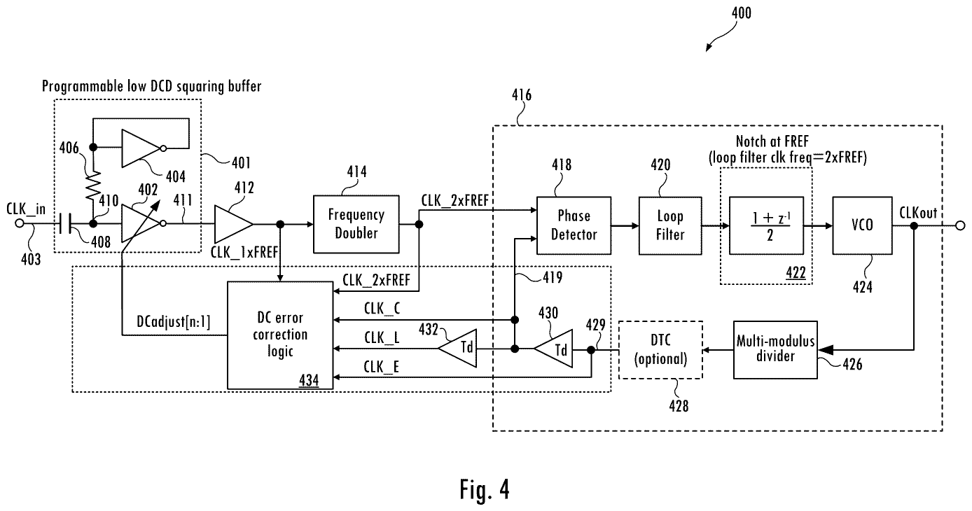

The use of the same reference symbols in different drawings indicates similar or identical items.

### DETAILED DESCRIPTION

Embodiments herein provide a digitally programmable squaring buffer that have low drift across temperature, process, and voltage variations. The improved squaring buffer described herein has inherently low duty-cycle error (also referred to herein as duty cycle distortion (DCD)) and therefore can be used as a stand-alone crystal oscillator buffer without a duty-cycle calibration loop for applications where a certain level of reference spurs can be tolerated. A simple one time DC calibration for the squaring buffer is further described herein. The duty-cycle of the squaring buffer is digitally calibrated. Once the squaring buffer is calibrated, the duty-cycle has very small drift due to temperature, process, and voltage variation. The duty-cycle change takes effect quickly (almost instantaneously) once the digital code changing the duty cycle is applied to the squaring buffer.

In addition, embodiments described herein provide a fast settling, simple yet effective duty-cycle calibration loop based on the clock phase relation of the divided down VCO clock in the PLL and the incoming frequency-doubled reference clock (CLK_2xFREF). Reference spurs are reduced by calibrating the duty-cycle of the incoming clock to ideally 50%. The correction point for the calibration is the squaring buffer. Thus, the duty-cycle calibration loop adjusts the slicing point (also referred to herein as trip point) of the squaring buffer to adjust the duty cycle to 50%. Embodiments of the duty-cycle calibration loop described herein are fast settling (e.g., <2 μsec) with low area and power overhead. Embodiments of the duty-cycle calibration loop have only digital circuitry, thus avoiding any large loop components (large resistors and capacitors) that could be needed by an analog loop. The duty-cycle calibration loop embodiments described herein achieve low-power by being turned off after calibration. Active power used during calibration is also low. The calibration scheme is particularly suitable for synthesizers where the calibration loop does not have to be on all the time (e.g., synthesizers for RF transceivers for packet based communication; WiFi, Bluetooth, Zigbee, . . . etc.)

An embodiment of the duty-cycle calibration loop is used in PLLs with time-to-digital (TDC) phase detectors. For PLLs with digital loop filters an embodiment includes a frequency notch placed at the spur location at the frequency fref to further attenuate reference spurs, where fref is the frequency of the signal (CLK_1xFREF) input to the frequency doubling circuit,. The various embodiments described herein are particularly useful for implementing low phase-noise/jitter fractional-N synthesizers with frequency doublers.

Thus, embodiments described herein include three main components. First is an improved squaring buffer with low duty cycle variation across PVT with fast digital duty-cycle adjustment and a simple DC mismatch calibration loop. The second main component is a duty-cycle error (DCD) calibration loop that reduces duty-cycle error and lowers the DCD to a level where the incoming PLL reference clock error is within the TDC range of a TDC implemented phase detector. A reduced DCD error also reduces the non-linearity induced jitter. The calibration loop is also useful in case the input clock to the squaring buffer has duty-cycle error. The third main component is the notch at fref that further attenuates the residual spur at +/−fref offset in the PLL output. Note that the three components can be used in various combinations. For example, the squaring buffer can be used alone. The squaring buffer and calibration loop can be used together with or without the frequency notch at fref.

FIG. 4 illustrates a system 400 illustrating the three main components. The squaring buffer circuit 401 receives an input clock signal (CLK_in) 403 from a clock source such as a crystal oscillator (XO). The squaring buffer circuit 401 includes the programmable main buffer (inverter 402), a replica buffer (inverter 404) having its input shorted to its output, and a resistor 406. The replica inverter 404 and resistor 406 function to supply a bias voltage at the trip point of inverter 402. With its input shorted to its output the replica inverter input/output nodes settle to a static value. The capacitor 408 AC-couples CLK_in to node 410. In an embodiment the inverter 402 supplies the square wave output signal 411 to one or more additional buffer stages 412. The squaring buffer circuit 401 provides a squaring buffer output clock (CLK_1xFREF) through one or more additional buffer circuits 412 to the frequency doubler circuit 414. The 1xFREF notation indicates the clock frequency is the same as the clock frequency (fref) as the input clock CLK_in.

The frequency doubler circuit 414 doubles the frequency of the squaring buffer output clock (CLK_1xFREF) and supplies the clock signal CLK_2xFREF to the PLL 416 as the PLL reference clock signal. The 2xFREF notation indicates the clock frequency is double the clock frequency (fref) of the input clock CLK_in.

The PLL 416 includes the phase detector 418, which compares the phase of the PLL reference clock signal to the feedback signal 419 and supplies the difference to loop filter 420. One or more embodiments include the notch filter 422 for the loop filter 420. The notch filter further reduces spurs at the frequency fref of the clock signals CLK_in and CLK_1xFREF. The loop filter controls the VCO to align the phase and frequency of the PLL reference clock signal (CLK_2xFREF) and the feedback signal 419. The feedback divider 426, implemented as a multi-modulus divider, divides the output of the VCO 424 and generates a divided clock signal 429 on which the feedback signal is based. The digital-to-time converter (DTC) 428 may be used in some embodiments of the PLL (e.g., fractional-N synthesizers to suppress quantization noise induced phase noise from the feedback divider) and omitted in others. In embodiments, the PLL 416 is an analog PLL with a traditional phase and frequency detector, a charge pump (not shown in FIG. 4), and an analog loop filter. In other embodiments PLL 416 is a digital PLL with a time-to-digital converter (TDC) used for the phase detector and a digital loop filter. Other PLL embodiments utilize a combination of analog and digital elements.

The system 400 further includes a duty-cycle (DC) error correction loop that includes DC error correction logic 434, the squaring buffer circuit 401, the frequency doubler circuit 414, and sample clock signals based on the divided clock signal 429 from the feedback divider 426. Each of these three major components of system 400 are discussed further herein.

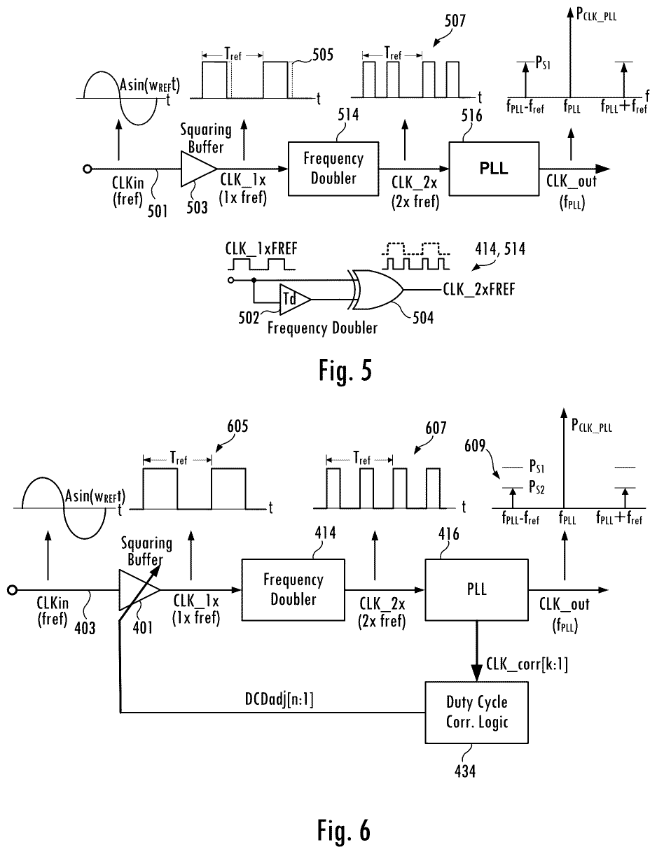

FIG. 5 illustrates the spurs resulting from a duty cycle error in the clock signal generated by the squaring buffer. The squaring buffer 503 (uncalibrated) receives the sinusoidal input clock signal (or other low edge rate clock signal) (CLKin) 501 having a frequency of fref. The low edge rate refers to the relatively slow transition between voltage levels for the signal such as occurs in a sine wave as compared to a fast transition that occurs, e.g., with a square wave. The squaring buffer 503 supplies a square wave output signal (CLK_1x) having a duty cycle error and a frequency of fref. The CLK_1x has a period T_{ref}. The dotted line 505 indicates where the falling edge of CLK_1x would be for a 50% duty cycle. The frequency doubler 514 doubles the clock frequency and supplies the clock signal CLK_2x having a frequency of 2×fref to PLL 516. The PLL 516 supplies an output clock signal CLK_out having a frequency of f_{PLL} and spurs with level P_{S1}. In an embodiment, the frequency doubler 514 doubles its input clock by XORing the incoming clock signal by delaying the incoming clock in delay buffer 502 and XORing the delayed version and the incoming clock together in XOR gate 504. The frequency doubler circuit 414 shown in FIG. 4 uses the same approach. As shown at 507 in FIG. 5 doubling the frequency results in a clock signal having a rising edge at each transition of the incoming clock signal and uneven periods due to the duty cycle error shown at 505. The doubled clock is then used as CLK_2x reference clock signal for the PLL.

FIG. 6 illustrates the spur reduction that occurs in an embodiment that includes a duty cycle correction loop such as shown in FIG. 4 to calibrate the squaring buffer circuit 401. In the embodiment of FIG. 6, the PLL 416 supplies duty cycle correction logic with correction signals (CLK_corr[k:1]), which the DC error correction logic 434 uses to determine the control signals (DCDadj[n:1]), which adjust the squaring buffer slicing point (also referred to herein as trip point) to correct the duty cycle. Other clock signals required by the duty cycle correction logic, such as CLK_1x from the squaring buffer and CLK_2x from the frequency doubler are also being supplied to the duty cycle error correction logic 434. As shown in FIG. 6 at 605, DCD calibration results in CLK_1x from the squaring buffer having a 50% duty cycle and the doubled clock signal CLK_2x having equal periods as shown in 607, which results in a spur reduction as shown at 609 from spur level P_{S1} to P_{S2}.

Referring back to FIG. 4, the squaring buffer circuit 401 is highly insensitive to PVT variations. The trip point (slicing point) tracks PVT. Across PVT, duty-cycle error variation is small, e.g., +/−0.4%, even as low as within +/−0.1% (when no mismatch is present between the replica inverter and the main squaring buffer inverter.) Mismatch in the inverters in the squaring buffer circuit 401 can increase the duty cycle error slightly. Note that temperature sensitivity is very low and therefore no re-calibration is required due to temperature change. For many designs, the duty cycle error falls within typical time-to-digital (TDC) input ranges (assuming TDC range is not very narrow) for digital PLLs having a TDC for phase detection. The main buffer 402 has a digitally adjustable duty cycle control that adjusts the trip point of the inverter 402. The digital correction has a fast response time, e.g., within a cycle of the square wave output of the squaring buffer circuit 401.

By way of example, assume the squaring buffer receives a clock signal having an input clock frequency fref=40 MHz. The period of the input clock (Tref) =25 nsec. In an embodiment, the maximum duty cycle error (DCDmax)=0.4% (one sided). That results in a maximum duty cycle error=100 picoseconds. The TDC output alters between values corresponding to +/−50 picoseconds. Referring still to FIG. 4, the squaring buffer achieves programmability by changing the strength of the main squaring buffer (inverter 402) while keeping replica inverter 404 unchanged as further explained herein. The programmable main squaring buffer circuit 401 allows duty-cycle change/trimming to be accomplished quickly. Duty cycle programmability is centered around 50% to reduce spurs such as those shown in FIG. 5. The squaring buffer circuit 401 can be used for traditional analog PLLs simply to reduce the reference spur without an additional calibration loop, if spur or jitter requirements are low enough for the particular application. That is because the incoming reference clock typically has very low duty-cycle error, assuming the input is coming from a crystal oscillator. The main source of duty-cycle error is the squaring buffer itself. The replica biased squaring buffer (401) has inherently low duty-cycle error, as mentioned above.

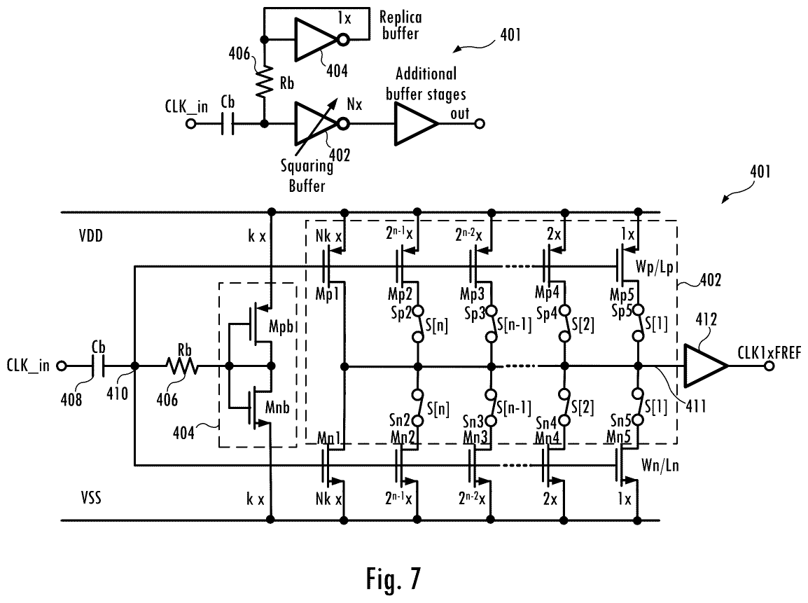

FIG. 7 illustrates additional details of an embodiment of the squaring buffer circuit 401. Additional one or more buffer stages 412 to further increase the clock edge rate are used in at least some embodiments. The squaring buffer circuit 401 utilizes multiple fingers formed by NMOS transistors Mn1-Mn5, PMOS transistors Mp1-Mp5, and corresponding switches (Sn2-Sn5, Sp2-Sp5), which selectively couple the NMOS transistors (Mn2-Mn5) and PMOS transistors (Mp2-Mp5) to the output CLK_1xFREF. The switches are opened or closed to adjust the strength of inverter 402 thereby changing the slicing point to adjust the duty cycle. The transistors Mp1 and Mn1 form a fixed portion of the inverter and the remaining transistors and switches form the programmable portion. The programmable portion is used to remove any mismatch between bias voltage at node 410 and the trip point voltage. Note that embodiments include additional duty cycle error adjustment range in order to correct any duty cycle error present on the input clock signal to the squaring buffer circuit 401.

In an embodiment the Snx switches for the NMOS transistors are shorter channel NMOS than the NMOS finger transistors and the Spx switches for the PMOS transistors are shorter channel PMOS transistors than the PMOS finger transistors. Mp1 and Mn1 are always coupled to the output signal 411. The control signals (DCDadj[n:1]) for the PMOS switches are shown as S[n]:S[1] and the control signals for the NMOS switches are also S[n]:S[1]. Although in the embodiment of FIG. 7, either the NMOS or PMOS side of a programmable branch is turned on since they receive the same switch signal, in other embodiments NMOS and PMOS switches for each branch are controlled separately to increase the duty-cycle adjustment granularity thus increasing the number of control signals in DCDadj[n:1].

When a duty-cycle error correction loop is available, the simple calibration approach described below is not typically needed since the correction loop brings the duty-cycle to around 50%. The simple calibration approach described below to correct DC mismatch is more applicable to the cases where no DC correction loop is available and the simple calibration approach functions to remove coarse duty-cycle error for applications where some amount of reference spur can be tolerated.

Transistors Mnb and Mpb for the replica bias inverter 404. The transistors Mnb and Mpb are a scaled down version of the fixed portion transistors of the squaring buffer first stage. That allows the replica bias buffer to remain small. The scaling is 1/N×(=k/Nk). In one or more embodiments switches that are always on are also included in the replica branch to improve matching. By way of example for the scaling the embodiment illustrated in FIG. 5, N=24, k=2, n=5. Of course many other scaling approaches can be used and the number of fingers and switches can vary according to system needs. In an example the width/length ratio for the PMOS transistors is Wp/Lp=4×1.44 μm/0.18 μm and for the NMOS transistors is Wn/Ln=4×1.26 μm/0.18 μm. Of course, those numbers are examples and the appropriate W/L ratios are chosen according to the process used in manufacturing and system needs. The illustrated embodiment provides N-bit binary duty-cycle programmability. Other embodiments such as a unary (thermometer decoded) approach or a segmented (combination of binary-unary) approach are also possible.

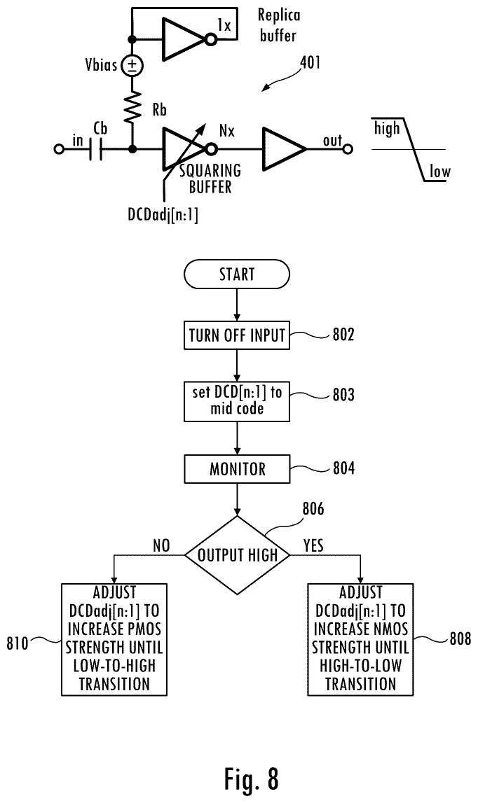

Mismatch between input bias point at node 410 and the ideal inverter trip point causes duty-cycle distortion. The main cause of this mismatch is device threshold voltage mismatches. Since the replica inverter is a 1/N×scaled version of the main squaring buffer fixed portion, the major contribution to the mismatch is from the devices in the replica inverter. FIG. 8 illustrates a simple calibration scheme to correct such mismatch. The squaring buffer circuit 401 is repeated in FIG. 8 for ease of reference. In 802 the sinusoidal (or other low edge rate) input signal is removed, e.g., using a switch (not shown) to isolate the squaring buffer from the input clock source. In 803 the switch control signals (S[n:1]) for the inverter are set to mid-level. In 804 the output of the squaring buffer is monitored. In embodiments, a state machine and/or a programmed microcontroller implements the simple calibration scheme illustrated in FIG. 8. In an embodiment the output is monitored by reading a flip-flop coupled to the output of the squaring buffer. In 806, if the squaring buffer output is HIGH, that means the bias voltage Vbias<Vtrip (assuming the squaring buffer output is inverting). Since the output is HIGH, the control logic adjusts NMOS/PMOS strength in 808 until the output transitions from HIGH to LOW. The adjustment increases the strength of NMOS (turns on one or more NMOS transistors in the inverter fingers by enabling one more switches shown in FIG. 7) and/or decreases the strength of PMOS transistors (turns off one or more PMOS transistors in the inverter fingers by disabling one or more switches shown in FIG. 7). Thus, the NMOS portion is at least relatively strengthened as compared to the PMOS. If the output of 806 is not HIGH meaning the squaring output buffer output is LOW, that means Vbias>Vtrip (assuming output is inverting) and the control logic adjusts the NMOS/PMOS strength in 810 until the squaring buffer output transitions from LOW to HIGH by decreasing the strength of the NMOS transistors by turning off one or more NMOS transistors in the inverter fingers by disabling one or more switches in the inverter (shown in FIG. 7) and/or increasing the strength of the PMOS transistors by turning on one or more of the PMOS transistors in the inverter fingers by enabling one more switches shown in FIG. 7. The simple calibration approach described in FIG. 8 to correct for DC mismatch between inverter 402 and inverter 404 can be used in embodiments lacking a calibration loop. Nominally, the default initial control code is set to mid-level (e.g., the switch control signals S[5:1]=10000).

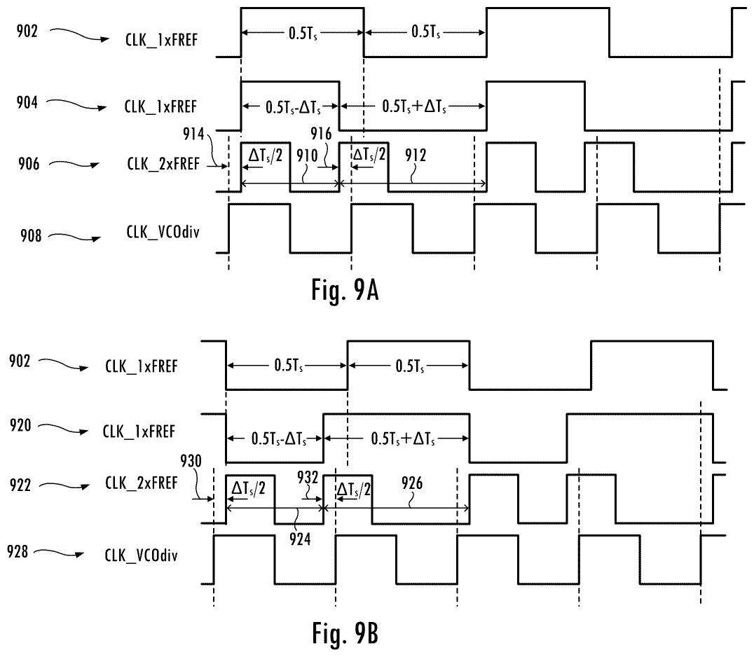

Referring now to FIGS. 9A and 9B, when the input clock signal (CLK_1xFREF) to the frequency doubler circuit has a non-50% duty cycle and the frequency doubled clock signal (CLK_2xFREF) is used as a reference for the PLL, the divided down PLL clock signal (CLK_VCOdiv) falls as “Early” and “Late” with respect to the PLL reference clock (CLK_2xFREF). FIG. 9A illustrates a duty-cycle error <50%. Waveform 902 shows CLK_1xFREF from the squaring buffer being supplied to the frequency doubler circuit having a duty cycle error=0 and a period of Ts. That is the desired duty cycle. Waveform 904 shows CLK_1xFREF being supplied to the frequency doubler circuit from the squaring buffer with a non-zero duty cycle error and still having a period of Ts. The duty cycle in waveform 904 is less than 50% and the error is shown as ΔTs. Waveform 906 shows the frequency doubled clock CLK_2xFREF from the clock doubler that is used as the PLL reference clock. Waveform 908 shows the PLL feedback clock signal CLK_VCOdiv (divided down from the VCO output clock) having a period of Ts/2 and no significant duty cycle error. The period of the frequency doubled clock CLK_2xFREF alternates between longer and shorter. The period 910 is 0.5Ts−ΔTs while period 912 is 0.5Ts+ΔTs. Those shortened and lengthened periods continue resulting in an average period of Ts/2. When the PLL is locked the amount of deviation in the feedback clock CLK_VCOdiv from the CLK_2xREF rising edge is shown at 914 as ΔTs/2 early. The deviation shown at 916 is ΔTs/2 late.

FIG. 9B illustrates a duty cycle error >50%. Waveform 902 shows CLK_1xFREF from the squaring buffer being supplied to the frequency doubler circuit having a duty cycle error=0 and a period of Ts. Waveform 920 shows CLK_1xFREF being supplied to the frequency doubler circuit from the squaring buffer with a non-zero duty cycle error and still having a period of Ts. The duty cycle in waveform 920 is greater than 50% and the error is shown as ΔTs. Waveform 922 shows the frequency doubled clock CLK_2xFREF from the clock doubler that is used as the PLL reference clock. Waveform 928 shows the PLL feedback clock signal CLK_VCOdiv (divided down from the VCO output clock) having a period of Ts/2 and no significant duty cycle error. The periods of the frequency doubled clock CLK_2xFREF again alternate between longer and shorter. The period 924 is 0.5Ts−ΔTs while period 926 is 0.5Ts+ΔTs. Those shortened and lengthened periods result in an average period of Ts/2. When the PLL is locked the amount of deviation in the feedback clock CLK_VCOdiv rising edges from the CLK_2xFREF rising edge are alternately ΔTs/2 ahead shown at 930 and Ts/2 behind shown at 932

A large duty cycle error results in a deviation that can be monitored by an early/late sampler (e.g., three sampling clocks each separated by 25 psec). A duty-cycle error of 1% for a 40 MHz CLK_1x_FREF is 250 psec. The VCO feedback clock rising edge is alternately 125 picoseconds ahead or behind the frequency doubled reference clock. In embodiments that information is used to reduce the duty cycle error. Initially with a duty cycle error the three sampler outputs from the early/late sampler are all ones “111” or all zeros “000”. The goal is to drive the sampled outputs to “011”, “001”, “110”, or “100” as explained further herein. The ambiguity of which direction to adjust is resolved by monitoring the polarity of the CLK_1xFREF clock signal that generates the frequency doubled CLK_2xFREF clock signal.

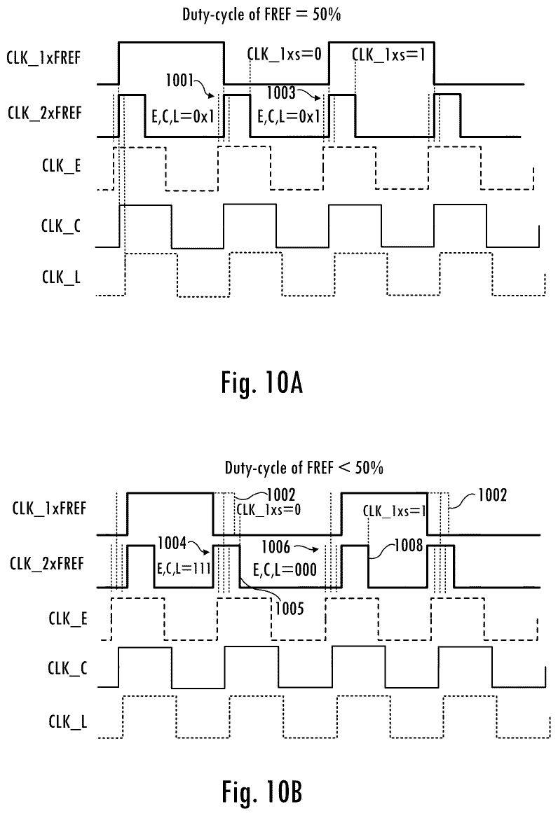

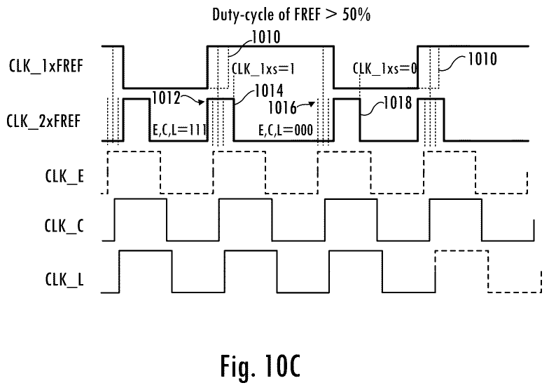

FIG. 10A-10C illustrate the use of three sampling clocks to determine the duty cycle error. FIG. 10A illustrates the case where the duty cycle of CLK_1xFREF is 50%, i.e., no duty cycle error. FIG. 10A shows the CLK_1xFREF waveform, the frequency doubled clock signal, CLK2xFREF, and the early (CLK_E), center (CLK_C), and late (CLK_L) sampling clock signals. Referring back to FIG. 4, the sampling clocks are shown as derived from the feedback signal 429. The sampling clocks sample the frequency doubled clock CLK_2xFREF on their rising edges as shown at 1001 resulting in E,C,L=0×1. The x results since the value is a don't care since no changes are required in PMOS/NMOS strength to achieve the desired duty cycle as long as the early and late samples have different values. Thus, the center sample C can be 1 or 0 when the early and late samples have different values. The sample clocks also sample the frequency doubled clock on their rising edges at 1003 resulting in E,C,L=0×1.

FIG. 10B illustrates the case where the duty cycle error of CLK_1xFREF is <50%. For a 50% duty cycle, CLK_1xFREF falling edge would occur at 1002. FIG. 10B also shows the frequency doubled clock signal, CLK2xFREF, and the early (CLK_E), center (CLK_C), and late (CLK_L) sampling clock signals. The sample clocks sample the frequency doubled clock CLK_1xFREF on their rising edges at 1004 (sampling times shown as dotted lines) resulting in E, C, L=111. CLK1xFREF is being sampled by the falling edge of CLK_2xFREF at 1005 and thus is 0. Note that in FIGS. 10A-10C the sampled 1xFREF clock is called CLK_1xs. The sample clocks sample the frequency doubled clock CLK_2xFREF on their rising edges at 1006 resulting in E, C, L=000. CLK1xFREF is being sampled by the falling edge of CLK_2xFREF at 1008 and thus CLK_1 xs is 1.

FIG. 10C illustrates the case where the duty cycle error of CLK_1xFREF is >50%. For a 50% duty cycle, CLK_1xFREF rising edge would occur at 1010. FIG. 10C also shows the frequency doubled clock signal, CLK2xFREF, and the early (CLK_E), center (CLK_C), and late (CLK_L) sampling clock signals. The sample clocks sample the frequency doubled clock CLK 2xFREF on their rising edges at 1012 (sampling times shown as dotted lines) resulting in E,C,L=111. CLK1xFREF is being sampled by the falling edge of CLK_2xFREF at 1014 and thus CLK_1xs is 1. The sample clocks sample the frequency doubled clock on their rising edges at 1016 resulting in E,C,L=000. CLK1xFREF is being sampled by the falling edge of CLK_2xFREF at 1018 and thus CLK_1xs is 0.

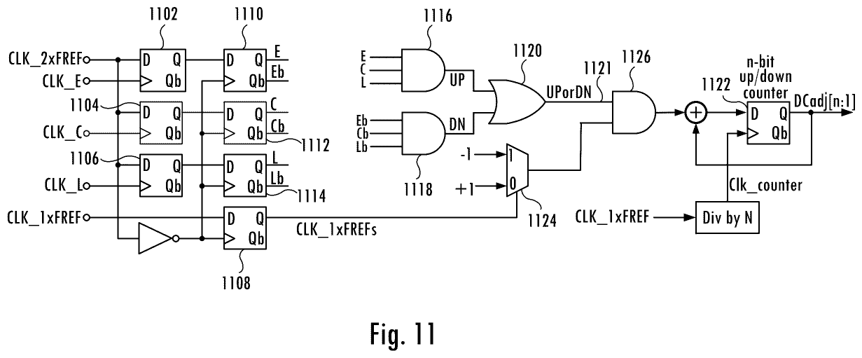

Referring back to FIG. 4, the multi-modulus divider (assuming the DTC 428 is omitted) supplies the divided signal 429 as the early signal CLK_E. The delay circuit 430 generates the center frequency CLK_C, which is also the feedback clock signal supplied to the phase detector 418. The second delay circuit 432 supplies the late clock signal (CLK_L). FIG. 11 illustrates a logical representation of an embodiment of the duty cycle (DC) error correction logic 434 (see FIG. 4) that implements the sampling by the ECL sampling clocks and supplies the control signals (DC_adj[n:1]) to adjust the PMOS/NMOS strength of the inverter 402 (see FIGS. 4 and 7) based on the sampling. Flip-flops 1102, 1104, and 1106 sample the frequency doubled clock signal CLK_2xFREF with respectively, CLK_E, CLK_C, and CLK_L. Flip-flop 1108 samples CLK_1xFREF with the falling edge of CLK_2xfref to determine the direction of the correction. The sampled CLK_1xFREF is named CLK_1xFREFs and is identical to the signal CLK_1xs of FIGS. 10A-10C. Flip-flops 1110, 1112, and 1114 respectively sample the outputs of flip-flops 1102, 1104, 1106 using the falling edge of CLK_2xFREF and supply the early (E) signal, the center (C) signal, and the late signal (L) and their complements Eb, Cb, and Lb. AND gate 1116 ANDs E, C, and L to provide the UP signal and AND gate 1118 ANDs Eb, Cb, and Lb to provide the down signal (DN). OR gate 1120 ORs the UP and DN signals. Thus, if E, C, and L are all 1s or all 0s the OR gate 1120 output is positive, and the up/down counter 1122 increments or decrements. The up/down counter 1122 supplies the DCadj[n:1] to control the switches Sp and Sn (see FIG. 4) to adjust the duty cycle. The direction of duty cycle adjustment is determined by the output of multiplexer 1124, which selects either a +1 or a −1 (or other increment or decrement values) according to the sampled value of CLK_1xFREF supplied by flip-flop 1108. The output of the multiplexer is logically combined with the UPorDN signal 1121 in AND gate 1126 to either increment the up/down counter by 1 or decrement the up/down counter by 1 when the UPorDN signal is asserted. The up/down counter 1122 provides the DCadj[n:1] signal to control the switches shown in FIG. 7 to adjust the slice point of inverter 402. The DC error correction logic 434 can be turned off when not in use to save power.

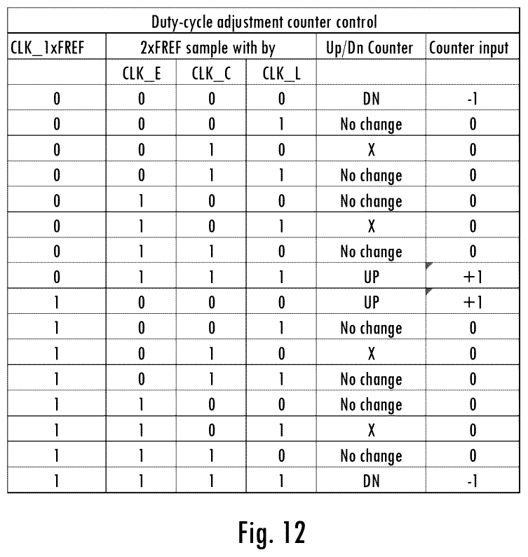

FIG. 12 shows a table illustrating the duty-cycle adjustment counter control based on the sampled value of CLK_1xFREF and the sampled values of CLK_2xFREF by the sample clocks. As illustrated in FIG. 12, the counter decrements when the sampled value of CLK_1xFREF and ECL are all identical: (0000 or 1111). For the CLK_1xFREF and ECL combinations equal to 0111 or 1000, the counter increments. For all other CLK_1xFREF and ECL combinations the counter is not updated. ECL=010 or 101 are invalid conditions and thus the counter output is x and the counter is not updated.

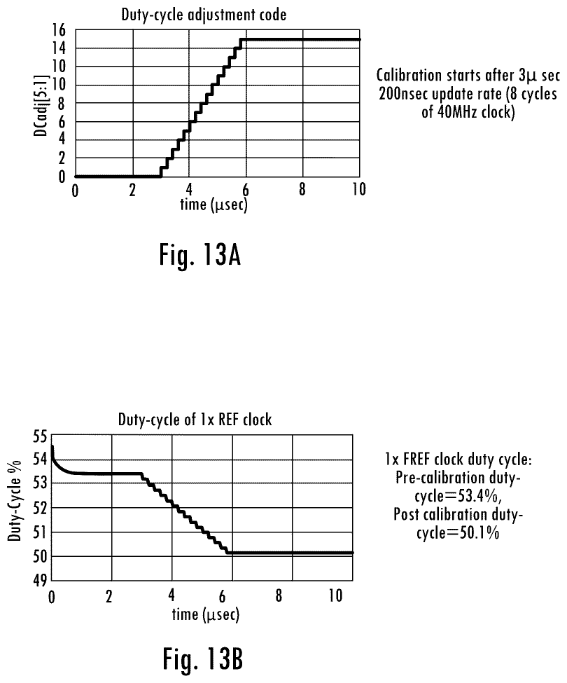

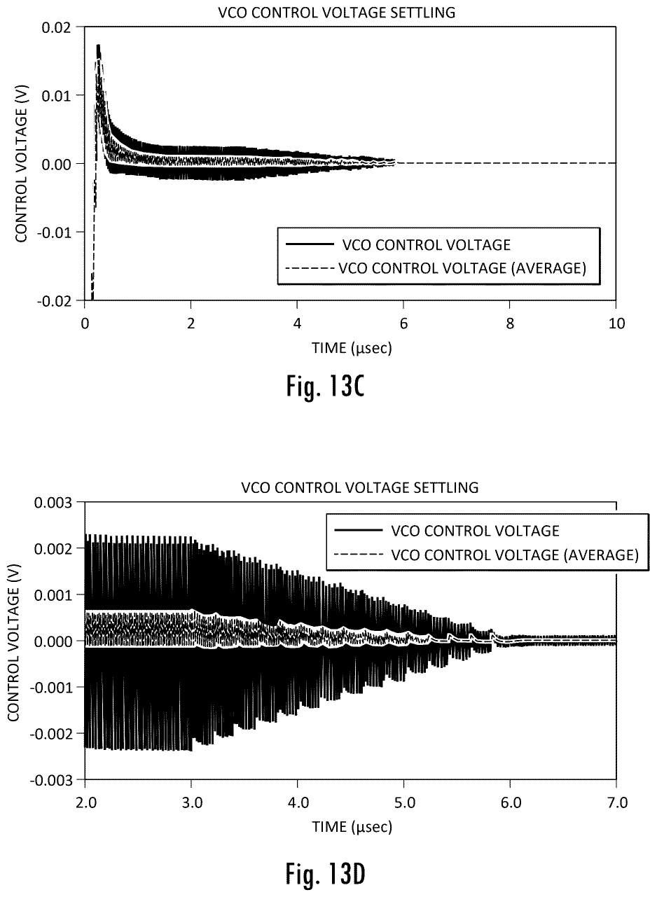

FIGS. 13A and 13B illustrate a duty cycle adjustment operation. In FIG. 13A the code to adjust duty cycle (DC_Adj[5:1]) is a 5 bit code that adjusts the switches in the inverter shown in FIG. 7. The operation to correct the duty cycle starts after the PLL settles, at 3 μsec and has a 200 nsec update rate (8 cycles of a 40 MHz clock). The duty cycle code (DC_Adj[5:1]) reaches a stable value at 6 μsec. FIG. 11B illustrates the effects of the changes in the duty cycle due to the changes in DC_Adj[5:1]). Before adjustment the duty-cycle is 53.4%. The duty cycle begins to change at 3 μsec and reaches a stable value at a 50.1% duty cycle with the final value of DC_Adj[5:1]. FIG. 13C illustrates the PLL VCO control voltage and average VCO control voltage waveforms from near 0 μsec, where the voltages have large swings from −0.02 V to ~+0.015V initially to when the VCO control voltage and average VCO control voltage settle by 6 μsec to ~0.00V and remain steady after that. FIG. 13D shows the period in greater detail from 2.0 μsec to 7 μsec and how the VCO control voltage settles to the average value. The average value is the average value of the last two samples with sampling clock rate of 2xFREF. FIG. 13D shows initial large swings between ~0.0023 and ~−0.0023 initially in the control voltage each cycle from 2.0 μsec to 3.0 μsec due to the uncalibrated duty cycle error. Those large control voltage swings are reduced as the duty cycle adjustment occurs between 3 and 6 μsec (see FIGS. 13A and 13B). By 6 μsec the duty cycle error is close to 0 and the VCO control voltage and VCO average control voltage have converged to ~0V.

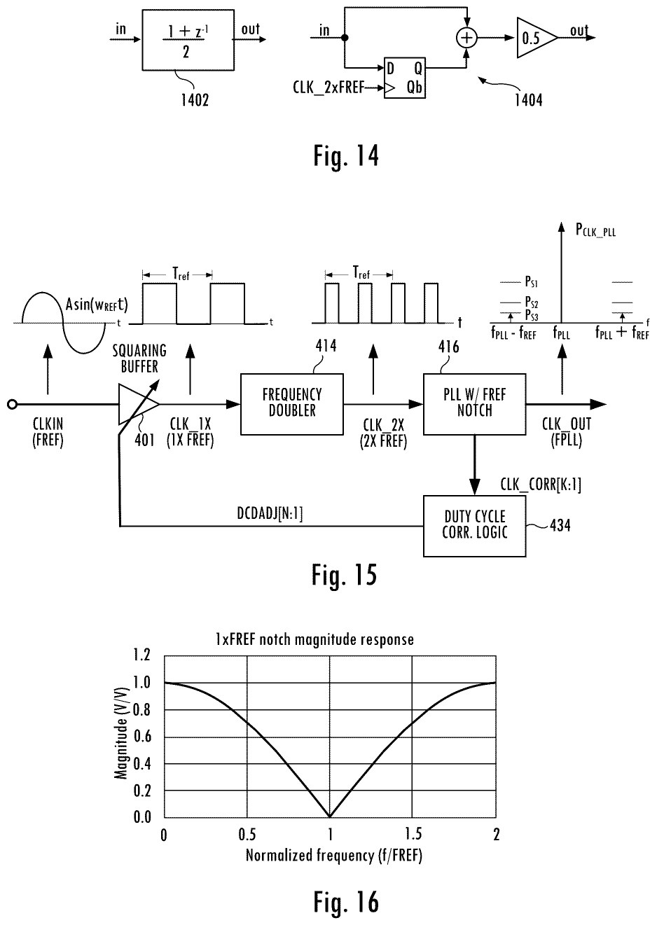

Referring back to FIG. 4, in embodiments with a digital loop filter, the notch in the loop filter at the frequency fref of CLK_1xFREF further attenuates the residual spur at fref in the PLL output. FIG. 14 illustrates an embodiment of the notch filter implementation with the z-domain representation shown in 1402 and a simplified block diagram shown at 1404, which provides an average of the last two samples. The loop filter and notch filter are clocked at 2×fref. The input into the notch filter is from the loop filter 420 and the output of the notch filter goes to VCO 424. FIG. 15 illustrates how the notch filter in the PLL at the frequency (fref) of the clock supplied to the frequency doubler circuit further reduces spurs on the PLL output to spur level P_{S3} (ideally complete removes them). FIG. 16 illustrates the notch filter magnitude response at fref. Note that ideally the notch filter completely removes the fref spur.

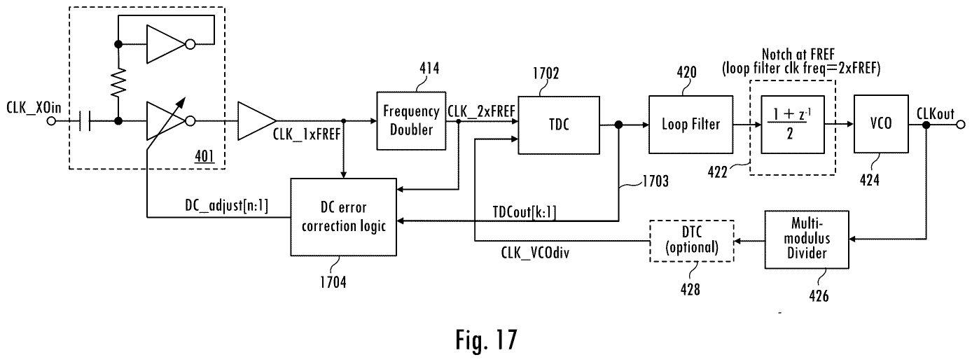

FIG. 17 illustrates an embodiment in which the phase detector is implemented as a time-to-digital converter (TDC) 1702, e.g., a Vernier line based phase detector. The TDC 1702 provides a TDC code TDCout[k:1] 1703 to DC error correction logic 1704 and to the loop filter 420. TDCout[k:1] indicates the phase error between the divided down VCO output clock CLK_VCOdiv and the frequency doubled clock CLK_2xFREF. The difference in TDCout[k:1] from one divided VCO clock cycle (code1) to the next clock cycle (code2) indicates the duty cycle error. The DC error correction logic 1704 tries to reduce code1-code2 to reduce duty cycle error. Thus, using the difference and using the information of the level (HIGH or LOW) of CLK_1xFREF to determine the direction of adjustment, the DC error correction logic 1703 adjusts DC_adjust[n:1] appropriately to reduce code1-code2 and thus reduce the duty cycle error.

FIG. 18 illustrates a timing diagram associated with the embodiment illustrated in FIG. 17. In the embodiment illustrated in FIG. 18, the clock signal CLK_1xFREF (with a frequency of fref) has a duty cycle less than 50%. The falling edge of CLK_1xFREF would occur at 1802 if the duty cycle was 50%. CLK_2xFREF (with a frequency of 2×fref) has shorter periods 1804 and longer periods 1806. The feedback clock signal CLK_VCOdiv with a frequency of 2×fref falls early with respect to CLK_2xFREF by ΔTs/2 as shown at 1808 and late by ΔTs/2 with respect to CLK_2xFREF as shown at 1810. TDCcount=code1 is associated with the first CLK_VCOdiv cycle 1804 and TDCcount=code2 is associated with the second clock cycle 1806. The output of the TDC is used to detect a duty cycle error and to adjust DC_adjust[n:1] if needed with the direction of the adjustment being based on the sampled value of CLK_1xFREF.

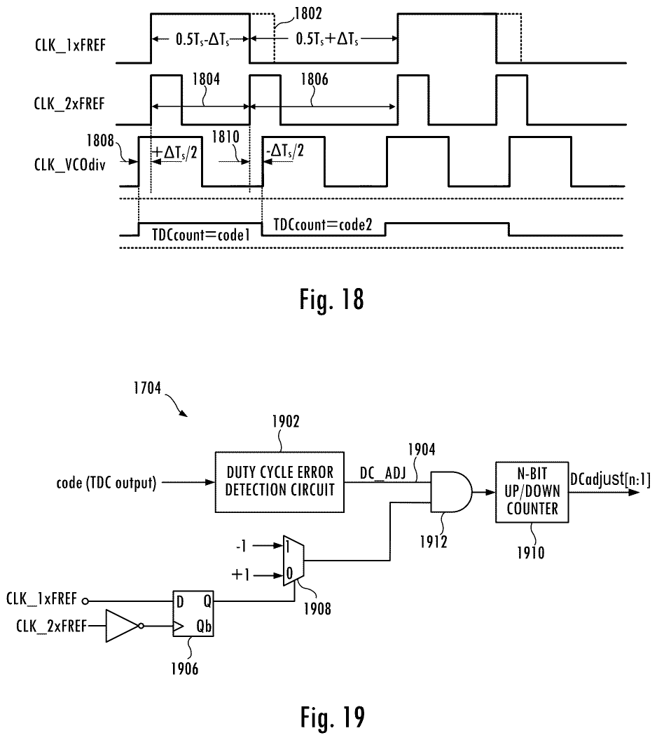

FIG. 19 illustrates an embodiment of the duty cycle error correction logic 1704. The duty cycle error detection block 1902 detects the existence of a duty cycle error. The detection block 1902 may detect the duty cycle error based on an absolute value of the difference between outputs of the TDC (e.g., between code1 and code2) being greater than a threshold. Alternatively, the duty cycle error may manifest itself at the TDC output as [+1, −1, +1, −1, . . . ] and detection block 1902 uses correlation to filter out noise and detect duty cycle error. If the detection block 1902 detects a duty cycle error, the DC_ADJ signal 1904 asserts. CLK_1xFREF is sampled by the falling edge of CLK_2xFREF in flip-flop 1906. The sampled value selects either the +1 or −1 input to multiplexer 1908 to either to cause the up/down counter 1910 to be incremented or decremented if the DC_ADJ signal is non-zero. The AND gate 1912 combines DC_ADJ and the output of multiplexer 1908 and supplies the result as the control signal to increment/decrement the up/down counter 1910. The up/down counter 1910 supplies the DC_adjust[n:1] control signals to adjust the duty cycle of the squaring buffer to closer towards a 50% value when needed. The DC error correction logic 1704 can be turned off when not in use to save power.

Thus, techniques for duty cycle error correction have been described. The description of the invention set forth herein is illustrative and is not intended to limit the scope of the invention as set forth in the following claims. The terms “first,” “second,” “third,” and so forth, as used in the claims, unless otherwise clear by context, are to distinguish between different items in the claims and do not otherwise indicate or imply any order in time, location or quality. Variations and modifications of the embodiments disclosed herein may be made based on the description set forth herein, without departing from the scope of the invention as set forth in the following claims.

What is claimed is:

1. An apparatus comprising:
a squaring buffer circuit, the squaring buffer circuit including,
a first inverter having a first inverter input coupled to an input signal and a first inverter output supplying a square wave signal;
a bias circuit to provide a bias voltage to the first inverter input, the bias circuit including,
a second inverter having a second inverter input shorted to a second inverter output; and
a resistor coupled between the second inverter output and the first inverter input.

2. The apparatus as recited in claim 1 wherein the first inverter includes a programmable portion.

3. The apparatus as recited in claim 2 wherein the second inverter is a scaled version of a fixed portion of the first inverter.

4. The apparatus as recited in claim 2 wherein the programmable portion of the first inverter comprises:
a plurality of PMOS transistors coupled between a first power supply node (VDD) and the first inverter output through a plurality of first switches; and
a plurality of NMOS transistors coupled between the first inverter output and a second power supply node (VSS) through a plurality of second switches.

5. The apparatus as recited in claim 4 further comprising a duty cycle error correction circuit responsive to a duty cycle error to adjust one or more control signals for one or more of the first switches and the second switches to reduce the duty cycle error.

6. The apparatus as recited in claim 5 further comprising:
a frequency doubler circuit coupled to the square wave signal and configured to supply a frequency doubled signal; and
a phase-locked loop coupled to the frequency doubled signal, the phase-locked loop including,
a phase detector coupled to the frequency doubled signal and to a feedback divider signal;
a loop filter coupled to the phase detector;
an oscillator coupled to the loop filter and configured to supply an oscillator output signal; and
a feedback divider coupled to the oscillator output signal and configured to supply the feedback divider signal.

7. The apparatus as recited in claim 6 further comprising a notch filter disposed between the loop filter and the oscillator.

8. The apparatus as recited in claim 6 wherein the duty cycle error correction circuit is configured to adjust one or more first inverter control signals to reduce the duty cycle error based, at least in part, on a timing relationship between the frequency doubled signal and the feedback divider signal.

9. The apparatus as recited in claim 8 further comprising:
a first delay circuit coupled to receive the feedback divider signal and configured to supply a first delay signal;
a second delay circuit coupled to the first delay signal and configured to supply a second delay signal; and
wherein the duty cycle error correction circuit is coupled to receive the feedback divider signal, the first delay signal, and the second delay signal, and the frequency doubled signal; and
wherein the duty cycle error correction circuit is configured to adjust the one or more control signals based on the feedback divider signal, the first delay signal, the second delay signal, the frequency doubled signal, and the square wave signal.

10. The apparatus as recited in claim 6 wherein the phase detector comprises a time to digital converter (TDC) based phase detector and the duty cycle error correction circuit receives signals from the TDC indicative of the duty cycle error.

11. A method for generating a square wave signal from a low edge rate input signal, the method comprising:
supplying the input signal to a first inverter of a squaring buffer circuit and supplying the square wave signal from the first inverter; and
generating a bias voltage for the first inverter using a second inverter having a second inverter input shorted to a second inverter output and a resistor coupled between the second inverter output and a first inverter input.

12. The method as recited in claim 11 further comprising calibrating a trip point of the first inverter to match the bias voltage.

13. The method as recited in claim 12 wherein calibrating the trip point of the first inverter comprises:
removing the low edge rate input signal;
monitoring the square wave signal;
adjusting NMOS/PMOS strength of the first inverter until the square wave signal transitions to a logical low responsive to the square wave signal initially being a logical high; and
adjusting NMOS/PMOS strength of the first inverter until the square wave signal transitions to a logical high responsive to the square wave signal initially being a logical low.

14. The method as recited in claim 12 wherein adjusting NMOS/PMOS strength comprises enabling or disabling at least one PMOS transistor in the first inverter, enabling or disabling at least one NMOS transistor in the first inverter, or enabling or disabling at least one PMOS transistor in the first inverter and enabling or disabling at least one NMOS transistor in the first inverter.

15. The method as recited in claim 11 further comprising correcting a duty cycle error of the square wave signal by adjusting a trip point of the first inverter to reduce the duty cycle error.

16. The method as recited in claim 15 further comprising:
doubling a frequency of the square wave signal and supplying a frequency doubled signal;
supplying the frequency doubled signal to a phase-locked loop (PLL); and
adjusting the trip point of the first inverter based, at least in part, on a timing relationship between the frequency doubled signal and a feedback divider signal of the PLL.

17. The method as recited in claim 16 further comprising reducing spurs in a PLL output signal using a notch filter in the PLL wherein the notch filter has a notch at a frequency of the input signal.

18. The method as recited in claim 16 further comprising adjusting one or more control signals supplied to the first inverter to adjust NMOS/PMOS strength of the first inverter to reduce the duty cycle error based, at least in part, on a timing relationship between the frequency doubled signal and the feedback divider signal.

19. The method as recited in claim 18 further comprising:
delaying the feedback divider signal in a first delay circuit and supplying a first delay signal;
delaying the first delay signal in a second delay circuit and supplying a second delay signal; and
determining the timing relationship and adjusting the one or more control signals based on the feedback divider signal, the first delay signal, the second delay signal, the frequency doubled signal, and the square wave signal.

20. An apparatus comprising:
a squaring buffer circuit, the squaring buffer circuit including,
a first inverter having a first inverter input coupled to a low edge rate input signal and a first inverter output supplying a square wave signal, the first inverter including a programmable portion;
a bias circuit to provide a bias voltage to the first inverter input, the bias circuit including,
a second inverter having a second inverter input shorted to a second inverter output, the second inverter being a scaled version of a fixed portion of the first inverter;
a resistor coupled between the second inverter output and the first inverter input;
a frequency doubler circuit coupled to the square wave signal and configured to supply a frequency doubled signal; and
a phase-locked loop coupled to the frequency doubled signal, the phase-locked loop including,
a phase detector coupled to the frequency doubled signal and to a feedback divider signal;
a loop filter coupled to the phase detector;
an oscillator coupled to the loop filter and configured to supply an oscillator output signal;
a feedback divider coupled to the oscillator output signal and configured to supply the feedback divider signal;
a duty cycle error correction circuit coupled to the square wave signal and wherein the duty cycle error correction circuit is responsive to a duty cycle error to adjust one or more duty cycle adjust signals to adjust PMOS or NMOS strength of the first inverter to reduce the duty cycle error; and
wherein the duty cycle error correction circuit is configured to adjust the one or more duty cycle adjust signals based, at least in part, on a value of the square wave signal.
